(19) United States
(12) Patent Application Publication
(10) Pub. No.: US 2008/0151675 A1
(43) Pub. Date: Jun. 26, 2008

(54) REDUCTION OF POWER CONSUMPTION OF AN INTEGRATED ELECTRONIC SYSTEM COMPRISING DISTINCT STATIC RANDOM ACCESS RESOURCES FOR STORING DATA

(75) Inventors: Cosimo Torelli, Cassina De Pecchi (IT); Danilo Rimondi, Mozzo (IT); Rita Zappa, Milano (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.I., Agrate Brianza (MI) (IT)

(21) Appl. No.: 11/963,145

(22) Filed: Dec. 21, 2007

(30) Foreign Application Priority Data
Dec. 22, 2006 (IT) VA2006A000081

(51) Int. Cl. G11C 5/14

(52) U.S. Cl. 365/227

(57) ABSTRACT

An integrated circuit includes an array of memory cells arranged in a plurality of sectors. Each sector includes a plurality of distinct random access memory resources able to be accessed differently in different modes. Peripheral circuitry is commonly shared by at least some of the sectors for addressing and reading/writing data. A respective dedicated controllable power supply line is coupled to each sector.

### FIELD OF THE INVENTION

This invention relates in general to integrated systems of large integration scale comprising distinct static random access storage resources.

### BACKGROUND OF THE INVENTION

In modern integrated systems, that is in complete functional systems integrated with large scale integration techniques (VLSI) on a single monolithic silicon chip, and generally referred to with the acronym SoC (System on Chip), static memories may typically have the greatest static power consumption

Static power consumption is due to leakage currents of the basic devices and may be strongly dependent on the size of the devices, on parameters of the fabrication process, particularly on the threshold voltage Vth, on dielectric thicknesses and also on working temperature. In memory arrays, the leakage is particularly relevant because of the very large number of cells that may be smaller than the minimum size allowed by the used fabrication technology. Moreover, the number of static memories deployed in modern SoCs increases with each step forward of the fabrication technology.

In mobile applications such as for portable phones and alike and in the automotive field, it may be desirable to limit as much as possible power consumption due to leakage without compromising the overall performances of the integrated system.

Besides the traditional integrated circuit technique known by the acronym RBB (Reverse Body Bias) and besides devices with multiple supplies (of different voltages), the most effective way of limiting the current absorbed in a stand-by state and under certain working conditions of the integrated system may be to keep enabled only a small part of the static memory resources and to disable the remaining part.

So far, the possibility of turning on and off the power supply to different static random access memory resources in a monolithically integrated system is achieved by using distinct memory blocks, each of which is integrated in areas or sections of the device to which it is possible to independently interrupt the supply, as contemplated in the execution program of a particular application by the SoC. Such an organization of known SoCs is schematically depicted in FIG. 1a.

There is a waste of silicon area. Moreover, designers may desirably take into account the electrical effects caused by the turning off of certain logic circuitry used by a memory block to be disabled.

There is an evident need or usefulness for an architecture of the above mentioned capabilities that occupies a reduced integration area, and that simplifies the realization of complex integrated electronic systems having reduced current consumption during stand-by phases and/or during the execution of applications that do not contemplate access to data stored in any or in some of the distinct random access memories that are part of the integrated system.

### SUMMARY OF THE INVENTION

These desirable objectives may be attained by the new architecture found by the applicants.

Basically, the gist of this invention that is outstandingly effective consists in realizing a single array or matrix of memory cells of total storage capacity comparable to the sum of the single storage capacities of two or more distinct random access memories for which a distinct management of turn off or turn on phases is contemplated in order to reduce static current absorption during particular functioning phases of the integrated system. Moreover, the peripheral circuitries, i.e. the logic circuits for decoding addresses of circuits for reading and writing data in and from addressed memory locations of the two or more sectors in which the array of cells is electrically subdivided, are unified.

The distinct sectors of the array of memory cells are individually supplied through respective supply lines connected to as many appropriate voltage supply sources through dedicated pins of the integrated device in case of controlled sources outside the device or to distinct controlled supply voltage sources present on the device. This approach may allow a reduction of about 5 to 15% of the global area, depending on the size of the distinctly powerable sectors of random access memory. This is primarily due to reductions of the overhead due to the peripheral circuitry that is substantially unified and to the simplification of electrical paths (reduction of the number of internal vias).

### BRIEF DESCRIPTION OF THE DRAWINGS

FIGS. 1a and 1b are respective schematic block diagrams of the known architecture of a monolithically integrated electronic system (SoC) according to the prior art and an architecture according to the present invention.

FIG. 2 is a block diagram of static memory resources in a monolithically integrated electronic system, according to an embodiment of the present invention.

FIG. 3 is a block diagram according to an alternative embodiment of the present invention that allows the programming of the number and the size of independently supplied sectors.

### DETAILED DESCRIPTION OF THE PREFERRED EMBODIMENTS

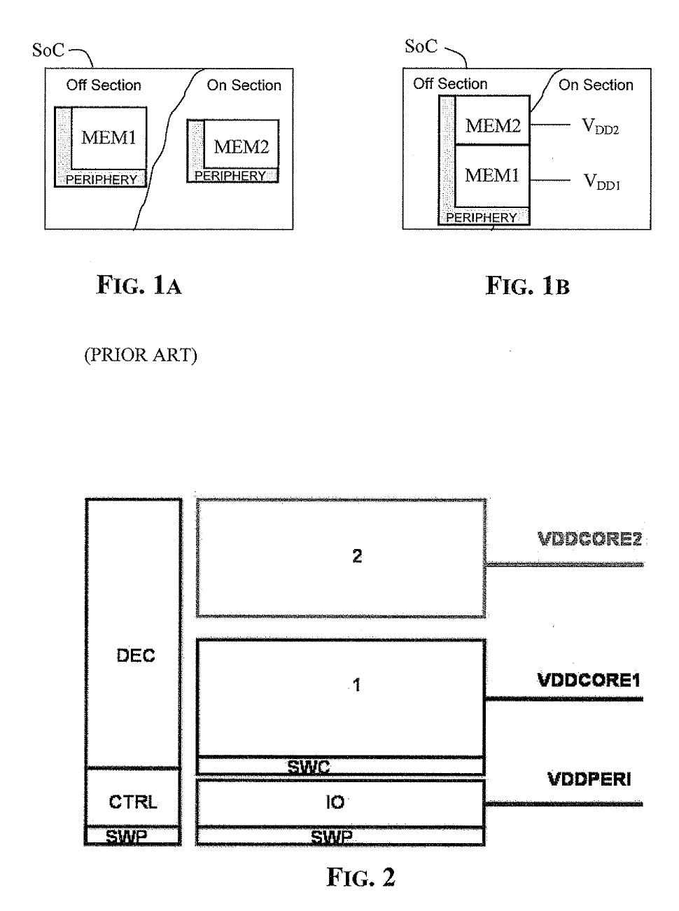

According to an embodiment, some or even all the distinct static random access memory resources that are defined in the design phase and that may be independently powered or disconnected as specifically commanded by the software during the execution of a certain application, by the integrated electronic system, includes an SKAM architecture in which the array of cells is subdivided into two or more regions, in the depicted example MEM1 and MEM2, each of which is independently supplied through distinct dedicated supply lines V_{dd1} and V_{dd2}, as schematically illustrated in FIG. 1b.

By comparing the architectures of FIG. 1b with the prior architecture depicted in FIG. 1a, it is noted that in the architecture of this invention the peripheral circuit of the unified array of memory cells are coherently unified.

In the illustrated example, the sector 1 or primary sector may be a memory resource that is always supplied for providing storage of data even when the data are not being used, depending on the particular application, executed by the integrated system. Sector 2 or secondary sector, like any other sector in which the single matrix of cells may be subdivided, represents a portion of the memory that on the contrary can be turned off during certain functioning phases of the device.

According to a possible variation of the embodiments of the integrated device, the memory cells belonging to distinct sectors that may be independently powered or turned off, can be realized with threshold values that differ from one sector to the other. For example, the sector 1, if it is to be powered without interruptions, can include cells with a relatively high threshold, while sector 2 can include low threshold cells in order to speed up data processing.

The peripheral circuitry comprises address decoders, the circuitry for controlling and managing the various operations to be carried out in the distinctly allowable memory sectors. The input/output circuitry of data to be stored or read may have optionally and preferably, as illustrated, a separate supply line even if, as an alternative, such a supply line may be in common with the supply of also an eventual primary sector 1 to be supplied without interruptions for storing essential data for carrying out the application.

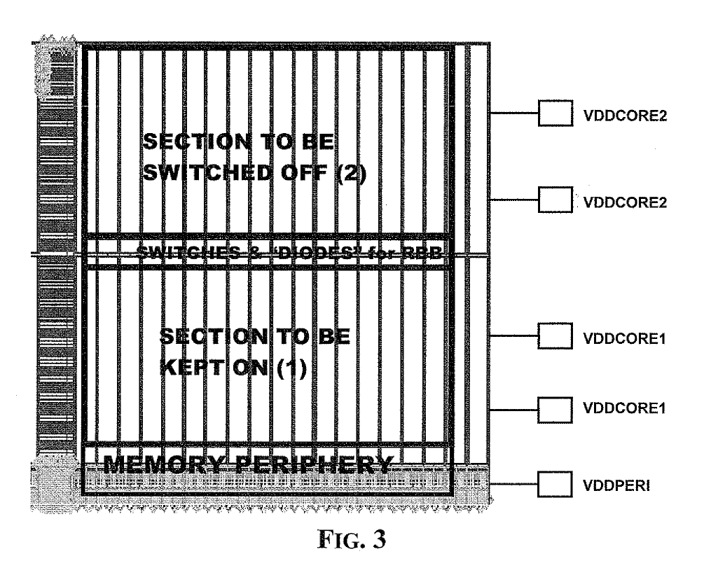

In the example of FIG. 2 is shown also blocks SWC and SWP that represent optional devices for implementing the well known Reverse Body Bias (RBB) technique. These circuits realize a compression of the rail-to-rail supply voltage inside the memory array for reducing current leakage during stand-by phases when only the peripheral circuitry and the primary sector 1 are kept on. If contemplated by the execution program of the particular application by the integrated electronic system, the peripheral circuitry and the primary sector may remain constantly powered.

The following table lists the possible configurations or functioning modes and the relative reduction effects on the stand-by current absorption.

| | | | | | | Isb | |
|---|---|---|---|---|---|---|---|
| | | | | | | Reduc- | NOISE |
| Mode | VDDC1 | VDDC2 | VDDP | SWP | SWC | tion | IMMUNITY |
| 1 | VDD | GND | VDD | OFF | OFF | + | ++ |
| 2 | VDD | GND | GND | OFF | OFF | +++ | ++ |
| 3 | VDD | GND | VDD | ON | OFF | ++ | ++ |
| 4 | VDD | GND | VDD | ON | ON | +++/+ | − |
| 5 | VDD | GND | GND | OFF | ON | ++++ | − |

The modes 1, 2 and 3 allow a reduction of the stand-by current without compressing the voltage levels of the memory cells. Current absorption may be further reduced in modes 4 and 5 at the cost of reducing noise rejection. In case the application being executed so permits, users may select modes 2 and 5 in which the unified peripheral circuitry of the distinct memory sectors is turned off.

The architecture of this embodiment allows also a higher degree of flexibility in defining the size of the primary memory sector and of secondary memory sectors or regions through a program operation.

In the tested sample embodiment, the monolithically integrated electronic system had first storage resources of 3 kB and secondary storage resources of 5 kB SPAM. In a low-leakage functioning mode of the device, the 5 kB SRAM could be turned off while the 3 kB SRAN kept uncorrupted data for the application stored therein.

With the architecture depicted in FIG. 2, it was possible to substitute two distinct integrated memories on the chip with a single 8 kB array of cells, thus saving a significant amount of area because of the substantial unification of the peripheral circuitries and simplification of data routing.

In order to keep the possibility of carrying out ECC controls and to keep permanently driven the output buffers of the memory device, the peripheral circuitry may be kept turned on. This choice depends on the particular application to be carried out and on the amount of leakage that may be attributed to the peripheral circuitry.

In case the number and storage capacity of different secondary memory sectors, that may be turned on or off independently by the application program, are programmable, the array of memory cells may comprise a certain relatively large number of sectors that can be electrically supplied through distinct supply lines, such as to determine a high “granularity” in terms of such numerous distinct memory portions. By programming, the most appropriate memory space subdivision for the particular application to be executed is established by the realization of the desired number of secondary sectors of appropriate capacity each including a sufficient number of the granular portions that may be powered as a group of lesser capacity. The turning on and off of the distinct secondary sectors of appropriate storage capacity may in this case be operated on the grouped memory portions forming the independently powerable secondary sector, such as for minimizing power consumption during different functioning phases of the device.

FIG. 3 depicts schematically an embodiment that allows an improved distribution of the supply voltage to the distinct sectors through a plurality of distribution lines in order to enhance the equipotentiality and reducing voltage drops.

1-4. (canceled)

5. An integrated circuit comprising:
an array of memory cells arranged in a plurality of sectors, each sector comprising a plurality of distinct static random access memory resources able to be accessed differently in different modes;
peripheral circuitry commonly shared by at least some of said sectors for addressing and reading/writing data; and
a respective dedicated controllable power supply line coupled to each sector.

6. The integrated circuit according to claim 5, wherein at least one of said sectors is to remain constantly supplied and the distinct static random access memory resources thereof have larger thresholds than thresholds of the distinct memory resources of other sectors of the array.

7. The integrated circuit according to claim 5, further comprising circuitry to compress a supply voltage inside the array for reducing current leakage during stand-by phases where one or more sectors are not powered.

8. The integrated circuit according to claim 5, wherein the sectors are programmably grouped to define a plurality of storage capacities.

9. An integrated circuit comprising:
an array of memory cells arranged in a plurality of sectors, each sector comprising a plurality of distinct memory resources able to be accessed differently in different modes;
a respective dedicated controllable power supply line coupled to each sector;
at least one of said sectors to remain constantly supplied and the distinct memory resources thereof having larger thresholds than thresholds of the distinct memory resources of other sectors of the array;
peripheral circuitry commonly shared by at least some of said sectors for addressing and reading/writing data; and
circuitry to compress a supply voltage inside the array for reducing current leakage during stand-by phases where one or more sectors are not powered.

10. The integrated circuit according to claim 9, wherein the sectors are programmably grouped to define a plurality of storage capacities.

11. The integrated circuit according to claim 9, wherein said distinct memory resources comprise distinct static random access memory resources.

12. An integrated circuit comprising:
an array of memory cells arranged in a plurality of sectors, each sector comprising a plurality of distinct memory resources able to be accessed differently in different modes;
peripheral circuitry commonly shared by at least some of said sectors for addressing and reading/writing data; and
a respective dedicated controllable power supply line coupled to each sector.

13. The integrated circuit according to claim 12, wherein at least one of said sectors is to remain constantly supplied and the distinct memory resources thereof have larger thresholds than thresholds of the distinct memory resources of other sectors of the array.

14. The integrated circuit according to claim 12, further comprising circuitry to compress a supply voltage inside the array for reducing current leakage during stand-by phases where one or more sectors are not powered.

15. The integrated circuit according to claim 12, wherein the sectors are programmably grouped to define a plurality of storage capacities.

16. A method for making an integrated circuit comprising:
arranging an array of memory cells in a plurality of sectors, each sector comprising a plurality of distinct static random access memory resources able to be accessed differently in different modes;
providing peripheral circuitry commonly shared by at least some of the sectors for addressing and reading/writing data; and
coupling a dedicated controllable supply line to each sector respectively.

17. The method according to claim 16, wherein at least one of the sectors is to remain constantly supplied and the distinct static random access memory resources thereof have larger thresholds than the thresholds of the distinct static random access memory resources that compose other sectors of the array.

18. The method according to claim 16, further comprising providing circuitry to compress a supply voltage inside the array for reducing current leakage during stand-by phases where one or more sectors are not powered.

19. The method according to claim 16, wherein the sectors are programmably grouped to define a plurality of storage capacities.

20. A method for making an integrated circuit comprising:
arranging an array of memory cells in a plurality of sectors, each sector comprising a plurality of memory resources able to be accessed differently in different modes;
coupling a dedicated controllable supply line to each sector respectively;
at least one of the sectors is to remain constantly supplied and the distinct memory resources thereof have larger thresholds than thresholds of the distinct memory resources that compose other sectors of the array;
providing peripheral circuitry commonly shared by at least some of the sectors for addressing and reading/writing data; and
providing circuitry to compress a supply voltage inside the array for reducing current leakage during stand-by phases where one or more sectors are not powered.

21. The method according to claim 20, wherein the sectors are programmably grouped to define a plurality of storage capacities.

22. The method according to claim 20, wherein the distinct memory resources comprise distinct static random access memory resources.
